(19) United States
(12) Patent Application Publication
(10) Pub. No.: US 2012/0142172 A1
(43) Pub. Date: Jun. 7, 2012

(54) PECVD DEPOSITION OF SMOOTH POLYSILICON FILMS

(76) Inventors: Keith FOX, Tigard, OR (US); Mandyam SRIRAM, Beaverton, OR (US); Bart VAN SCHRAVENDIJK, Sunnyvale, CA (US); Jennifer O'LOUGHLIN, Portland, OR (US); Joe WOMACK, Tigard, OR (US)

(21) Appl. No.: 13/313,422

(22) Filed: Dec. 7, 2011

Related U.S. Application Data
(63) Continuation-in-part of application No. 12/970,853, filed on Dec. 16, 2010.
(60) Provisional application No. 61/420,731, filed on Dec. 7, 2010.
(60) Provisional application No. 61/317,656, filed on Mar. 25, 2010.
(60) Provisional application No. 61/382,465, filed on Sep. 13, 2010.
(60) Provisional application No. 61/382,468, filed on Sep. 13, 2010.
(60) Provisional application No. 61/394,707, filed on Oct. 19, 2010.

(51) Int. Cl. H01L 21/20; C23C 16/52; C23C 16/50

(52) U.S. Cl. 438/488; 438/478; 118/697; 257/E21.09

(57) ABSTRACT

Smooth silicon and silicon germanium films are deposited by plasma enhanced chemical vapor deposition (PECVD). The films are characterized by roughness (Ra) of less than about 4 Å. In some embodiments, smooth silicon films are undoped and doped polycrystalline silicon films. The dopants can include boron, phosphorus, and arsenic. In some embodiments the smooth polycrystalline silicon films are also highly conductive. For example, boron-doped polycrystalline silicon films having resistivity of less than about 0.015 Ohm cm and Ra of less than about 4 Å can be deposited by PECVD. In some embodiments smooth silicon films are incorporated into stacks of alternating layers of doped and undoped polysilicon, or into stacks of alternating layers of silicon oxide and doped polysilicon employed in memory devices. Smooth films can be deposited using a process gas having a low concentration of silicon-containing precursor and/or a process gas comprising a silicon-containing precursor and H₂.

### CROSS-REFERENCE TO RELATED APPLICATIONS

This application claims benefit of prior U.S. Provisional Application No. 61/420,731 filed Dec. 7, 2010, titled “PECVD DEPOSITION OF SMOOTH POLYSILICON FILMS” naming Fox et al. as inventors, which is herein incorporated by reference in its entirety and for all purposes. This application is also a continuation-in-part of prior U.S. application Ser. No. 12/970,853 filed Dec. 16, 2010, titled “SMOOTH SILICON-CONTAINING FILMS” naming Fox et al. as inventors, which claims priority to U.S. Provisional Patent Application Ser. No. 61/317,656, titled “IN-SITU PLASMA-ENHANCED CHEMICAL VAPOR DEPOSITION OF FILM STACKS,” and filed on Mar. 25, 2010; U.S. Provisional Patent Application Ser. No. 61/382,465, titled “IN-SITU PLASMA-ENHANCED CHEMICAL VAPOR DEPOSITION OF FILM STACKS,” and filed on Sep. 13, 2010; U.S. Provisional Patent Application Ser. No. 61/382,468, titled “SMOOTH SILANE-BASED FILMS,” and filed on Sep. 13, 2010; and U.S. Provisional Patent Application Ser. No. 61/394,707, titled “IN-SITU PLASMA-ENHANCED CHEMICAL VAPOR DEPOSITION OF FILM STACKS,” and filed on Oct. 19, 2010, the entirety of which are hereby incorporated herein by reference for all purposes.

### FIELD OF THE INVENTION

The present invention pertains to the methods of depositing smooth silicon films. Specifically, the invention is useful in semiconductor processing, particularly in the field of fabrication of three-dimensional (3D) memory devices.

### BACKGROUND OF THE INVENTION

Patterning film stacks for three-dimensional (3D) memory devices can be difficult. Some conventional atomic layer deposition (ALD), chemical vapor deposition (CVD), high-density plasma chemical vapor deposition (HDP-CVD) and plasma-enhanced chemical vapor deposition (PECVD) processes for depositing film layers may produce unacceptably rough films, cause unacceptable interfacial mixing between film layers, and may have interfacial defects caused by vacuum breaks between successively deposited film layers. The resulting rough film interfaces and interfacial defects may be magnified by subsequently deposited layers as the film stack is built, so that the top surface of the film stack may be unacceptably rough for downstream patterning processes. Further, interfacial defects within the film stack may lead to structural and/or electrical defects in the 3D memory device.

### SUMMARY OF THE INVENTION

Smooth silicon and silicon germanium films are highly desirable for many applications employing stacks of layers of materials. Such films are particularly needed for 3D memory fabrication, where stacks containing more than 10, 20, or even 50 layers are deposited on a substrate, and are then patterned. Methods provided herein allow for deposition of smooth silicon and silicon germanium films by PECVD. In some embodiments, smooth films, characterized by surface roughness of less than about 4 Å, are deposited by PECVD at a temperature of between about 350-650 degrees C., and at a deposition rate of at least about 100 Å/minute, such as at a rate of at least about 100 Å/minute. In some embodiments formed films are polycrystalline silicon films, which are substantially free of Si—H bonds, based on Fourier transform infrared (FT IR) spectroscopy. Films can be doped or undoped, where the dopants can include, but are not limited to, boron, arsenic, and phosphorus. Advantageously, films which are both smooth and conductive can be prepared by provided methods. For example boron-doped smooth polycrystalline silicon films having resistivity of less than about 0.015 Ohm-cm, such as less than about 0.01 Ohm-cm can be deposited by provided methods. The dopant can be present in the film in a concentration of up to about 30% atomic. Advantageously, stable boron-doped silicon films having boron concentrations of at least about 10% atomic can be deposited by provided methods.

In one aspect, a method for forming a smooth silicon film on a substrate in a plasma-enhanced chemical vapor deposition apparatus comprises: supplying a process gas comprising a silicon-containing reactant, such as silane or disilane, to a PECVD apparatus; and forming a plasma in the PECVD apparatus to deposit a smooth silicon film on the substrate. The deposition is performed using conditions that result in films having surface roughness (Ra) of less than about 4 Å.

In accordance with one embodiment, the smooth silicon or silicon germanium films are deposited using process conditions which employ a process gas with a very low concentration of a silicon-containing precursor or germanium-containing precursor. For example, in one embodiment, the method of depositing a smooth silicon film comprises providing a process gas comprising less than about 2% of silane by volume. The process gas can further comprise an inert gas, such as helium. Further, it was unexpectedly discovered that addition of hydrogen (H₂) to the process gas results in improvement of smoothness of the films, even at relatively higher concentrations of a silicon-containing precursor in the process gas. For example, in the absence of hydrogen in the process gas, silane concentration in the process gas preferably should not exceed about 1%, to achieve smooth films. When hydrogen is added to the process gas, smooth films can be obtained with silane concentrations of up to about 2%. In some embodiments, the process gas comprises a silicon-containing precursor (e.g., silane) at a concentration of up to about 1% by volume of the process gas, more preferably between about 0.2% and 0.75%, and an inert gas (e.g., helium) in the absence of hydrogen. In other embodiments, the process gas comprises a silicon-containing precursor (e.g., silane) at a concentration of up to about 2% by volume of the process gas, more preferably between about 0.15% and 1.75% (e.g., 0.18-1.72%), an inert gas (e.g., helium) and hydrogen, preferably at a hydrogen concentration of between about 1 and 15% by volume.

In some embodiments the process gas further comprises a source of a dopant. For example, boron-doped polycrystalline silicon films can be prepared by adding a boron-containing reactant (e.g. diborane) to the process gas. Arsenic-doped, and phosphorus-doped films are prepared by using a process gas comprising an arsenic-containing reactant (e.g., arsine) or phosphorus-containing reactant (e.g., phosphine) respectively. Advantageously, smooth and conductive polycrystalline boron-doped films are prepared by provided methods. For example, smooth doped silicon films with resistivity of less than about 0.015 Ohm cm, such as less than about 0.01 Ohm cm are prepared. In some embodiments, the smooth, boron-doped films are prepared using a process gas comprising diborane and silane, where the volume ratio of diborane to silane is between about 0.011 and 0.035.

In another embodiment diborane is used to reduce the amount of Si—H bonds in the formed film. In this embodiment diborane can be added in a small amount, and the resulting silicon film is not necessarily boron-doped, or may have a very low concentration of boron. For example, the process gas comprising diborane and silane, where the diborane to silane molar ratio is less than about 0.011, is used in some embodiments to form polycrystalline silicon films that are substantially free of Si—H bonds, as measured by FT IR.

The smooth doped and smooth undoped silicon films can be used in a variety of stacks, such as stacks used in 3D memory devices. In one embodiment doped smooth silicon film (e.g., boron-doped silicon film) provided herein is incorporated into a stack comprising at least one layer selected from the group consisting of undoped silicon, undoped silicon germanium, silicon oxide, and silicon nitride. In one embodiment, an undoped smooth silicon film provided herein is incorporated into a stack, comprising at least one layer selected from the group consisting of doped silicon, silicon oxide, and silicon nitride. In some embodiments, a smooth silicon germanium film provided herein is incorporated into a stack comprising at least one layer selected from the group consisting of doped silicon, silicon oxide, and silicon nitride. Preferably, but not necessarily, at least some, and more preferably each of the layers of materials in the stack are smooth layers, having surface roughness of less than about 4 Å, preferably less than about 3 Å. The layers of materials in the stacks typically alternate, e.g., stacks can contain alternating layers of smooth doped silicon and undoped silicon, alternating layers of smooth doped silicon and silicon germanium, alternating layers of smooth undoped silicon and silicon oxide, alternating layers of smooth undoped silicon and silicon nitride, alternating layers of smooth silicon germanium and a layer selected from the group consisting of doped silicon, silicon nitride, and silicon oxide. Preferably, at least some of the stacks are deposited in an apparatus without a vacuum break. For example, in some embodiments a silicon nitride, a silicon oxide or silicon germanium film is deposited over a smooth silicon film (doped or undoped), without a vacuum break.

In some embodiments the smooth silicon films described herein are formed without an anneal. This can be beneficial for the thermal budget of the device fabrication process, and may also be advantageous for structures that have limited stability at higher temperatures. In other embodiments, the films can be annealed after deposition by heating at a temperature of at least about 400° C.

The deposited films and/or stacks can be photolithographically patterned. The smoothness of deposited films and stacks is highly advantageous for photolithography, as it can be preformed with great precision. In some embodiments the methods provided herein further include applying photoresist to the substrate, exposing photoresist to light, patterning the resist and transferring the pattern to the substrate and selectively removing the photoresist from the substrate.

In another aspect, a PECVD apparatus for depositing a smooth silicon film is provided. The apparatus includes a PECVD process chamber having an inlet for introduction of a process gas; and a controller comprising program instructions for conducting a process comprising supplying a process gas comprising a silicon-containing reactant to the PECVD process chamber; and forming a plasma in said process chamber to deposit a smooth silicon film on the substrate, wherein roughness of the deposited film is less than about 4 Å.

In another aspect a system is provided which includes an apparatus described herein and a stepper.

In another aspect a non-transitory computer machine-readable medium comprising program instructions for control of a PECVD apparatus is provided, wherein the program instructions include code for performing methods provided herein. In some embodiments the instructions include code for supplying a process gas comprising a silicon-containing reactant to the PECVD process chamber and forming a plasma in the process chamber to deposit a smooth silicon film on the substrate, wherein roughness of the deposited film is less than about 4 Å.

These and other features and advantages of the present invention will be described in more detail below with reference to the associated drawings.

### BRIEF DESCRIPTION OF THE DRAWINGS

FIG. 1 is a process flow diagram illustrating a smooth silicon deposition method in accordance with an embodiment of the invention.

FIG. 2 is an experimental plot illustrating dependence of surface roughness of a PECVD polycrystalline silicon film on a flow rate of silane.

FIG. 3A is a process flow diagram illustrating a smooth silicon deposition method in accordance with an embodiment of the invention.

FIG. 3B is an experimental plot illustrating dependence of surface roughness of a PECVD polycrystalline silicon film on a flow rate of silane precursor in the absence and in the presence of hydrogen in the process gas.

FIG. 4A is a process flow diagram illustrating a smooth silicon deposition method for conductive doped polysilicon in accordance with an embodiment of the invention.

FIG. 4B is an experimental plot illustrating dependence of bulk resistivity of a polycrystalline boron-doped silicon film on a diborane/silane ratio in the process gas.

FIG. 4C is an experimental plot illustrating dependence of bulk resistivity of a polycrystalline boron-doped silicon film on a diborane/silane ratio in the process gas at different temperatures.

FIG. 5 shows a schematic depiction of a PECVD apparatus that is suitable for deposition of smooth silicon layers in accordance with embodiments provided herein.

FIG. 6 is a schematic cross-sectional view of a multi-layer stack which incorporates a layer of smooth silicon or smooth silicon germanium.

FIG. 7 is a schematic cross-sectional view of a deposited 15-layer stack containing alternating layers of smooth boron-doped polysilicon and smooth silicon oxide.

### DETAILED DESCRIPTION

Reference will now be made in detail to specific embodiments of the invention. Examples of the specific embodiments are illustrated in the accompanying drawings. While the invention will be described in conjunction with these specific embodiments, it will be understood that it is not intended to limit the invention to such specific embodiments. On the contrary, it is intended to cover alternatives, modifications, and equivalents as may be included within the spirit and scope of the invention as defined by the appended claims. In the following description, numerous specific details are set forth in order to provide a thorough understanding of the present invention. The present invention may be practiced without some or all of these specific details. In other instances, well known process operations have not been described in detail in order not to unnecessarily obscure the present invention.

Smooth silicon and silicon germanium films are provided and methods of forming such films by PECVD are described. Smooth films, as used in this description, refer to films having surface roughness of less than about 4 Å. Surface roughness refers to an Rₐ value determined by atomic force microscopy (AFM). In many examples provided herein surface roughness is measured on a 1,000 Å thick film deposited on a bare silicon substrate. It is understood that, as used in the claims, surface roughness refers to the actual Ra of deposited films irrespective of their thickness (that is, if a 200 Å film is deposited, roughness of such film is measured).

In some embodiments smooth films having surface roughness of less than about 3 Å are deposited. It has been demonstrated that in many embodiments the surface roughness of films provided herein is stable to thermal treatment and does not increase after an anneal at 1100° C.

Smooth silicon films include undoped and doped silicon films, where the suitable dopants include but are not limited to boron, phosphorus, and arsenic. The dopant is typically present at a concentration of less than about 30% atomic. Both amorphous and polycrystalline silicon are within the scope of the embodiments provided herein. It is particularly advantageous that smooth doped and undoped polycrystalline silicon films that have little or no Si—H bonds as evidenced by a small peak or no peak at 2000 cm⁻¹ in FT-IR spectra, can be deposited by PECVD methods provided herein. In some embodiments, it is preferable to reduce the hydrogen content in the film, and in many cases the deposited films are polycrystalline and/or are substantially hydrogen-free (with hydrogen concentration of less than about 1% atomic), that is, undoped silicon contains substantially only silicon, doped silicon contains substantially only silicon and the dopant, and silicon germanium contains substantially only silicon and germanium. In other embodiments, hydrogen may be present in the films at a concentration of less than about 2% atomic. Generally, presence of Si—H bonds is detrimental to film stability and large concentrations of hydrogen in the films are undesired.

Further, methods for depositing smooth and conductive doped silicon films are provided. In some embodiments the doped silicon films have a surface roughness of less than about 4 Å and a resistivity of less than about 0.015 Ohm-cm as-deposited. For example smooth boron-doped films having a resistivity of 0.004 Ohm-cm as-deposited (without an anneal) were formed by provided methods. The conductivity of the formed films can be optionally further increased by annealing. For example, smooth boron-doped polysilicon films having a resistivity of about 0.001 Ohm-cm were obtained after the films were annealed at 1070° C. using a Rapid Thermal Anneal tool with a dwell time of 1 second. Advantageously, distribution of dopant in the films formed by this method is homogeneous and the films are stable. Further, in some embodiments, highly doped films, having a dopant concentration of at least about 10% atomic can be obtained.

The films can be deposited at a temperature range of between about 350-650 degrees C., and at a deposition rate of at least about 100 Å/minute. In some embodiments, smooth films having substantially no Si—H bonds can be advantageously deposited at a low temperature of less than about 450° C. In other embodiments, where thermal considerations are not critical, deposition can be performed at higher temperatures, e.g., at between about 570-650° C., as higher temperatures were found to be beneficial of increasing conductivity of doped films. In many embodiments the films are deposited at a pressure of between about 0.5-8 torr. While in general both HF RF plasma and LF RF plasma can be employed in the plasma discharge, in some embodiments it is preferable to use HF RF plasma only.

The composition of the process gas is of particular importance for deposition of smooth silicon films and smooth silicon germanium films. The process gas includes a silicon-containing precursor, such as silane, disilane, or any SiₓH_{y} precursor. The process gas typically further includes an inert gas or a mixture of inert gases, e.g., helium, argon, neon, xenon, krypton, nitrogen or mixtures thereof. The process gas, in some embodiments, further includes hydrogen (H₂), which was found to dramatically improve smoothness of the formed films. In some embodiments, the process gas includes very small amounts of diborane used as a scavenger of Si—H bonds. When doped silicon films are deposited, the process gas further includes a source of dopant, such as diborane, arsine or phosphine.

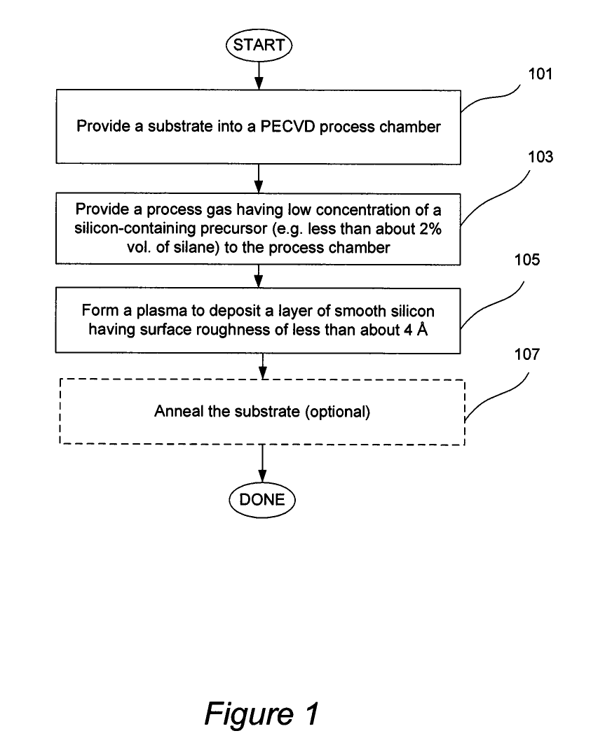

It was unexpectedly discovered that smooth silicon and silicon germanium films can be formed if very low concentrations of silicon-containing reactant (e.g., silane or disilane) are employed in the process gas used in PECVD deposition. FIG. 1 illustrates a process flow diagram for depositing a smooth doped or undoped silicon film in accordance with this embodiment. The process starts in 101 by providing a substrate to a PECVD process chamber. The substrate, such as a semiconductor wafer, is secured on a pedestal, and a process gas is introduced into the process chamber as shown in 103. The process gas typically includes a silicon-containing reactant (e.g., silane or disilane), and one or more inert gases, such as helium, argon, and nitrogen. In some embodiments, the process gas further includes hydrogen. In those instances, when doped silicon is deposited, the process gas further includes a source of dopant. For example the process gas can include a boron-containing reactant (e.g., diborane or boron trichloride) for deposition of a boron-doped silicon film, a phosphorus-containing reactant (e.g., phosphine) for deposition of a phosphorus-doped silicon film, and an arsenic-containing reactant (e.g., arsine) for deposition of an arsenic-doped silicon film. As shown in operation 103, the process gas contains low concentration of a silicon-containing reactant. When silane is used, preferably its concentration should be less than about 2% if the process gas includes hydrogen, and less than about 1% if the process gas is hydrogen-free. Illustrative suitable silane concentration range for a hydrogen-free process gas is between about 0.2-1% of the total process gas volume. Illustrative silane concentration range for a hydrogen-containing process gas is between about 0.18-1.72% of the total process gas volume. It is understood, that the concentration of silicon-containing reactant should be sufficiently high so as to provide acceptable deposition rates, since rates of deposition decrease with decreasing concentration of silicon-containing reactant. The deposition rates in the methods provided herein are typically 100 Å/minute or higher, such as 120 Å/minute or higher. In operation 105, a plasma is formed in the process chamber such as to deposit a smooth silicon film on a substrate, where the film has a roughness of less than about 4 Å, such as less than about 3 Å, as-deposited. Deposition can be performed at a temperature of between about 350-650° C., and at a pressure of between about 0.5-8 Torr. In some embodiments, the flow rate of silane is between about 0.1-250 sccm, while the flow rates of each of the inert gases can vary, but typically do not exceed 25,000 sccm. Hydrogen (if present) can have a flow rate of up to 5,000 sccm, and in some embodiments 5% B₂H₆ is introduced at a flow rate of up to about 400 sccm. In some embodiments, the plasma is High Frequency (HF) radio frequency (RF) plasma having a power of up to about 5,000 W. It is understood that flow rates and plasma power can differ depending on the size of a PECVD apparatus chamber. The exemplary flow rates and plasma power values provided herein and throughout the description are suitable for a process chamber configured to process four 300 mm wafers simultaneously. One of skill in the art will understand how to scale these parameters to a process chamber of any size.

Referring again to FIG. 1, the process may continue by an optional operation 107, in which the film can be annealed by heating the substrate after deposition. In some embodiments, anneal is performed by heating the substrate at a temperature of at least about 450° C., such as at least about 650° C. It is noted, that in many embodiments anneal is not necessary and is not performed because films, as deposited, have sufficiently low surface roughness and generally acceptable properties for incorporation into a 3D memory stack.

The principles and methods illustrated by the process flow diagram of FIG. 1 also apply to deposition of silicon germanium films. These films are deposited using a process gas comprising a silicon-containing reactant (e.g., silane), a germanium-containing reactant (e.g., germane), an inert gas (e.g., helium, argon or nitrogen), and, optionally, hydrogen, where the concentration of silicon-containing reactant and of a germanium-containing reactant is relatively small (e.g., less than about 2% by volume).

Specific illustrative examples of the method of claim 1 are provided. In one example boron-doped polycrystalline silicon film was deposited at a temperature of 450° C. and at a pressure of 5 Torr using the process gas having the following composition: silane (provided at a flow rate of 40 sccm); helium (provided at a flow rate of 16,000 sccm) and 5% B₂H₆ (provided at a flow rate of 60 sccm). High frequency (HF) radio frequency (RF) plasma was applied at a power of 1000 W to deposit boron-doped polysilicon film at a rate of 200 Å/minute. The roughness of the film was 3 Å, as measured on a 1000 Å thick film.

In another example, boron-doped polycrystalline silicon film was deposited at a temperature of 550° C. and a pressure of 5 Torr using the process gas having the following composition: silane (provided at a flow rate of 40 sccm); helium (provided at a flow rate of 16,000 sccm), 5% B₂H₆ (provided at a flow rate of 60 sccm). High frequency (HF) radio frequency (RF) plasma was formed at a power of 1000 W to deposit boron-doped polysilicon film at a rate of 190 Å/minute. The roughness of the film was 2.5 Å, as measured on a 1000 Å thick film.

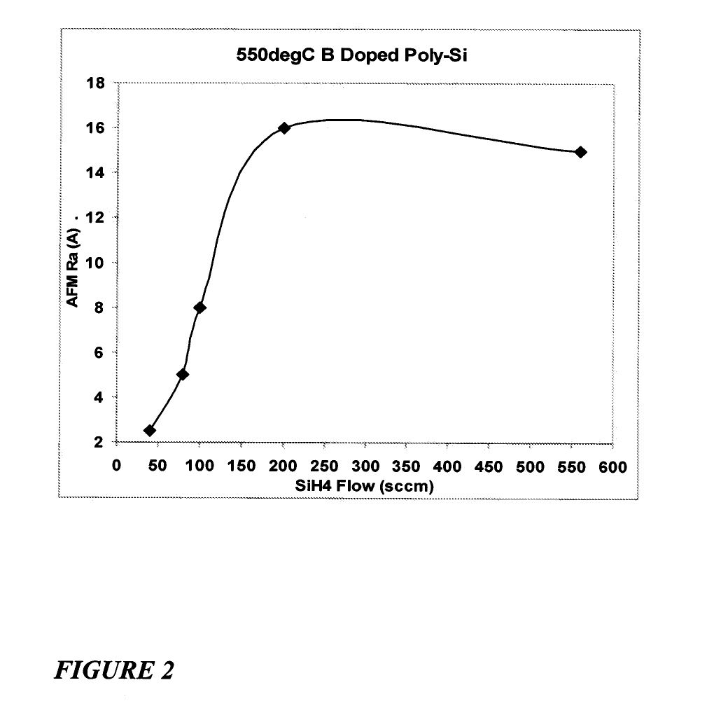

As it was mentioned, the finding that the use of very low concentrations of silicon-containing precursor in the process gas result in reduction of surface roughness was unexpected. FIG. 2 is a graph which illustrates surface roughness of a boron-doped polysilicon film deposited at 550° C. as a function of silane flow rate. It can be seen that at low silane flow rates (corresponding to low concentration of silane in the process gas), the roughness of the deposited films unexpectedly and significantly decreases. This behavior could not be predicted based on the behavior of the curve at higher flow rates of silane (e.g., at above 200 sccm).

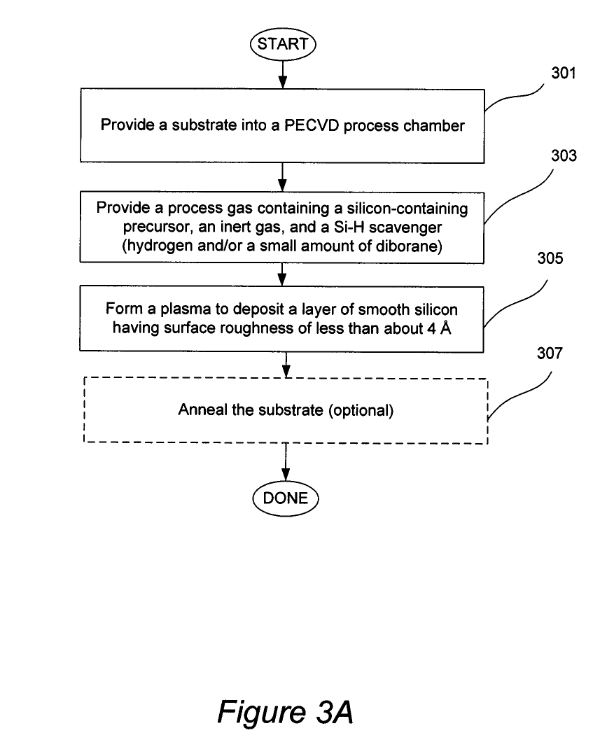

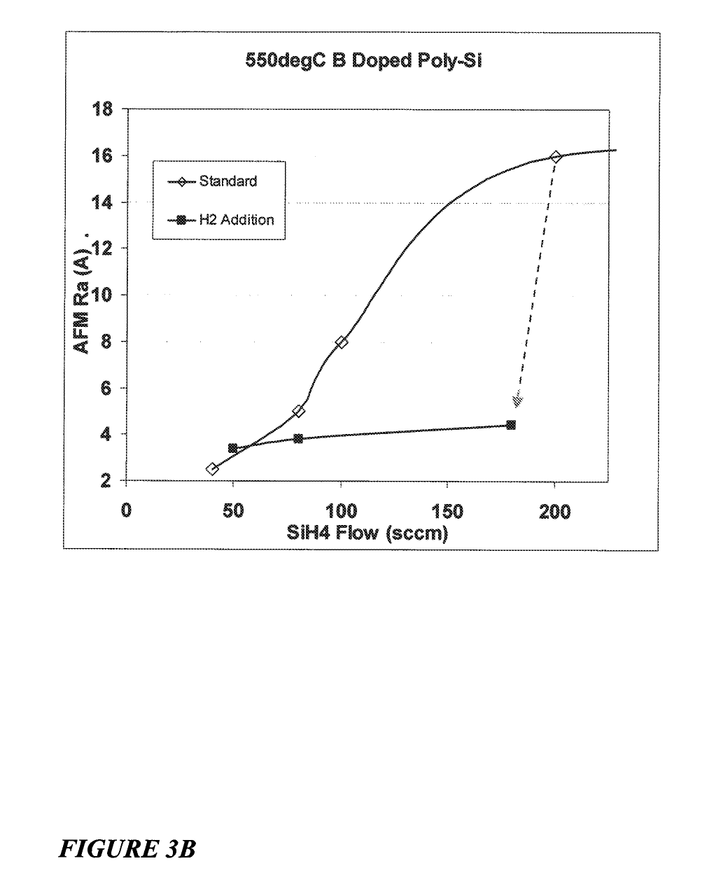

In another embodiment illustrated in FIG. 3A, a method for depositing smooth silicon films using a process gas comprising hydrogen (H₂) and/or small amounts of diborane (B₂H₆) is provided. Addition of these gases results in dramatic reduction of Si—H bond content in the formed films, and these components are sometimes referred to as “H-scavengers”. Advantageously, addition of H-scavengers to the process gas allows for deposition of Si—H free smooth silicon films at low temperatures, at which in the absence of scavengers films having considerable amounts of Si—H bonds are formed. Thus, addition of scavengers provides films that are substantially free of Si—H bonds at temperatures of less than about 500° C., such as less than about 450° C. It is noted that diborane, when provided in very small concentrations, may not necessarily serve as a source of substantial amounts boron dopant, and the resulting films may be substantially undoped or have very small amounts of incorporated boron, making them substantially non-conductive, with resistivities greater than about 10⁴ Ohm-cm, such as between about 10⁵-10⁹ Ohm-cm.

It was unexpectedly discovered that addition of hydrogen and/or small amounts of diborane to the process gas results in improved smoothness of resulting films, even at relatively higher concentrations of a silicon-containing reactant. For example, in the absence of hydrogen gas in the process gas, smooth silicon films can be obtained with the process gas containing 1% or less of silane. When hydrogen is added to the process gas, silicon films of the same low roughness can be obtained using process gas in which silane concentration can be up to 2%. This is advantageous because higher deposition rates of smooth films can be achieved when deposition is conducted with a hydrogen-containing process gas. Similar benefits in deposition rate increase can be obtained by using small amounts of diborane. In many embodiments, deposition rates of smooth silicon films with surface roughness of less than about 4 Å, obtained by this method are at least about 200 Å/minute. In some embodiments, deposition rates of silicon films with surface roughness of less than about 4.5 Å, obtained by this method are at least about t 400 Å/minute.

In the method shown in FIG. 3A, similarly to the method illustrated by FIG. 1, the process starts in 301 by providing a substrate to a process chamber. In operation 303 a process gas containing hydrogen and/or small amounts of diborane is provided. The process gas further includes a silicon-containing reactant (e.g., silane at a concentration of less than about 2%) and an inert gas, such as helium, argon or nitrogen. In the embodiments that use hydrogen, its concentration in the process gas is preferably between about 1-15%. When diborane is used in this embodiment, it is used not as a dopant source, but as a scavenger which reduces the amount of Si—H bonds in the formed silicon films. Thus, the films formed from the process gas containing small amounts of diborane are generally considered electrically non-conductive. In illustrative embodiments, the concentration of diborane is less than about 1.1% of silane provided in the process gas. In operation 305 a plasma is formed in the PECVD chamber to deposit smooth silicon film having roughness of less than about 4 Å. In many embodiments, the formed films are substantially free of Si—H bonds based on FT-IR and do not require annealing. In some embodiments, the deposited film is optionally annealed after deposition, as shown in operation 307.

Deposition according to the method illustrated in FIG. 3A can be performed at a temperature of between about 350-650° C., and at a pressure of between about 0.5-8 Torr. In many embodiments, the flow rate of silane is, preferably, relatively low, e.g., between about 0.1-250 sccm, while the flow rates of each of the inert gases can vary, but typically do not exceed 25,000 sccm. Hydrogen can have a flow rate of up to 5,000 sccm. When diborane is used as a scavenger, 5% B₂H₆ is introduced into the process gas at a flow rate of 1% of the silane flow rate. In some embodiments, the plasma is high frequency (HF) radio frequency (RF) plasma having a power of up to about 5,000 W. In some embodiments silane is provided at a flow rate of between about 40 to 100 sccm; 5% B₂H₆ is provided at a flow rate that is between about 3 to 5% of silane flow (which is <1% on pure B₂H₆ basis); inert gases are provided at a flow rate of between about 12,000 to 20,000 sccm; and hydrogen is provided at a flow rate of between about 500 to 2500 sccm; HF RF power is between about 500 and 2500 watts and pressure is between about 4 and 6 torr.

Smooth silicon germanium films can be deposited using the same principles as in the method illustrated in FIG. 3A. Specifically, smooth silicon germanium films can be prepared using a process gas comprising a silicon-containing reactant (e.g., silane), a germanium-containing reactant (e.g., germane), an inert gas, and an “H” scavenger (hydrogen and/or diborane).

In one specific example boron-doped polycrystalline silicon film was deposited at a temperature of 550° C. and a pressure of 5 Torr using the process gas having the following composition: silane (provided at a flow rate of 180 sccm); helium (provided at a flow rate of 16,000 sccm) and 5% B₂H₆ (provided at a flow rate of 120 sccm), and hydrogen (provided at a flow rate of 2000 sccm). High frequency (HF) radio frequency (RF) plasma was formed at a power of 1,000 W to deposit boron-doped polysilicon film at a rate of 500 Å/minute. The roughness of the formed film was 3.8 Å, as measured on a 1,000 Å thick film.

An illustration of hydrogen addition effect is provided in the graph shown in FIG. 3B, which illustrates a dependence of surface roughness for boron-doped films deposited at 550° C. on the flow rate of silane. For one curve the process gas does not contain hydrogen. For the second curve, the process gas contains hydrogen. It can be seen that surface roughness of deposited films is dramatically improved via addition of hydrogen, particularly at higher flow rates of silane.

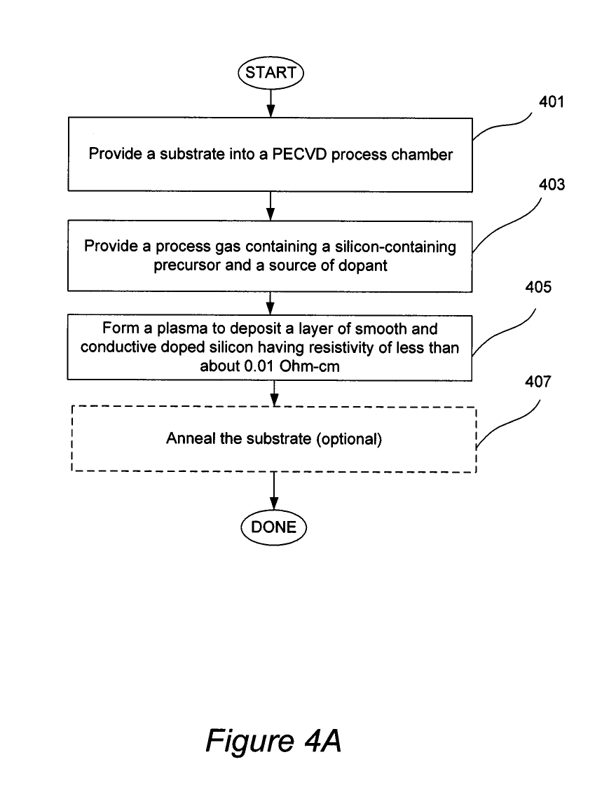

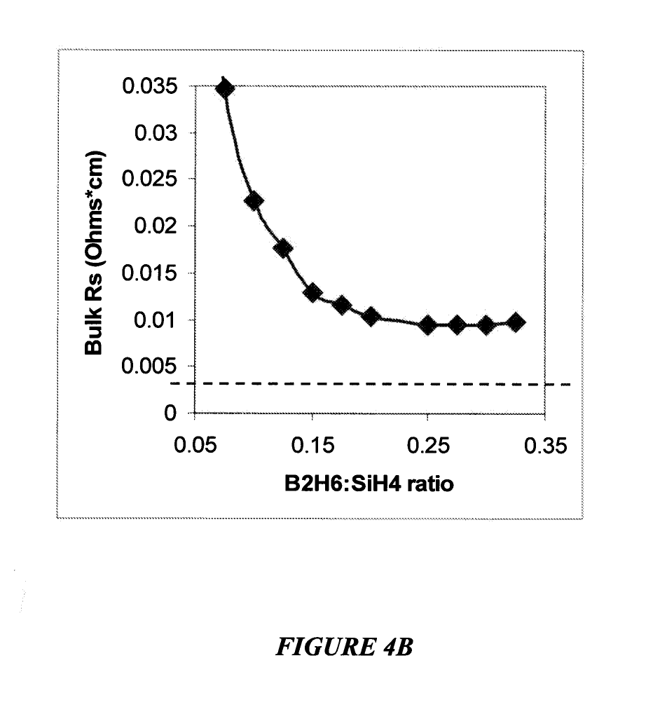

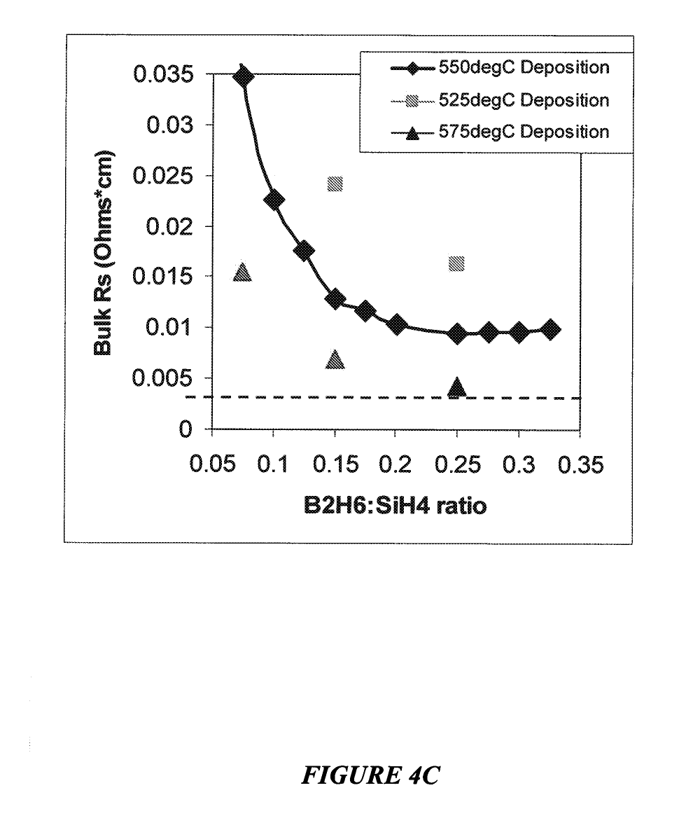

Addition of hydrogen to the process gas can be employed in deposition of both doped and undoped silicon films, as well as in deposition of silicon germanium films. Addition of small amounts of diborane can be used in deposition of substantially undoped silicon films, or silicon films doped with a dopant other than boron (if other dopant sources are used in the process gas) or silicon germanium films. Deposition of boron-doped polycrystalline silicon films from a process gas having higher concentrations of boron-containing reactant, will be described in detail with reference to FIG. 4A.

FIG. 4A is a process flow diagram for a method of depositing doped silicon films that are both smooth and conductive. Specifically, doped polysilicon films with surface roughness of less than about 4 Å, such as less than about 3 Å and resistivity of less than about 0.015 Ohm cm can be obtained by this method. Conventionally, deposition of doped polysilicon was performed by low pressure chemical vapor deposition (LPCVD), which is a method that does not employ plasma, but typically requires either an anneal at a high temperature (often at 900° C. or higher) to promote diffusion of dopant into the film, or implantation of dopant into a formed film, which results in films that have relatively higher resistivity, or in situ deposition which suffers from nonuniformity of dopant distribution in the film. PECVD methods described herein can provide polysilicon films with high conductivity and low roughness, at relatively low temperatures (350-650° C.) and at relatively high deposition rates of at least about 100 Å/minute. As increase in deposition temperature generally increases the conductivity of deposited films, in some embodiments, preferred deposition temperature is between about 400-650° C., such as between about 550-650° C.

In the method illustrated in FIG. 4A, the substrate is provided into the PECVD process chamber in operation 401. A process gas is introduced into the process chamber, where the process gas includes a silicon-containing reactant (e.g., silane), a dopant-containing reactant (e.g., diborane), an inert gas, and, optionally, hydrogen. The composition of the process gas is configured such as to provide films having high smoothness and conductivity. Specifically, in the case of silane and diborane, in some embodiments, the concentration of silane in the process gas is preferably less than about 2% (e.g., less than about 1%), while the diborane/silane ratio is between about 0.011 and 0.35. The plasma is formed in the PECVD chamber, as shown in operation 405 to deposit a doped polysilicon film having low roughness and low resistivity (e.g., resistivity of less than about 0.0015 Ohm cm, such as less than about 0.001 Ohm cm). Finally, an optional anneal can be performed in operation 407 by heating the substrate.

Deposition can be performed at a temperature of between about 350-650° C., such as between about 450-650° C., and, in some embodiments, at between about 550-650° C. and at a pressure of between about 0.5-8 Torr. In some embodiments, the flow rate of silane is between about 0.1-250 sccm, while the flow rates of each of the inert gases can vary, but typically do not exceed 25,000 sccm. Hydrogen (if present) can have a flow rate of up to 5,000 sccm, and in some embodiments 5% B₂H₆ is introduced at a flow rate of up to about 400 sccm. The HF RF power is typically up to about 5,000 W. In one example, SiH4 flow is from about 40 to 100 sccm; 5% B2H6 flow is from about 30 to 60 sccm; inert gases flow is from about 12,000 to 20,000 sccm; hydrogen flow is from about 500 to 2500 sccm; HF RF power is from about 500 to 2500 watts and pressure is from about 4 to 6 torr.

FIG. 4B is a plot illustrating dependence of resistivity of a boron-doped polysilicon film deposited at 550° C., on the borane/silane volume ratio. It can be seen that at very low borane/silane ratios, the resistivity is high, and is decreasing with the increasing ratio. It has also been shown that the surface roughness does not significantly depend on the borane/silane ratio and does not significantly increase with increasing temperature of deposition within provided ranges. In fact there is a moderate increase in surface roughness for films deposited at 450° C. as compared to films deposited at higher temperatures.

Further, it was shown that resistivity of deposited films decreases with increasing temperature of deposition. This is illustrated by FIG. 4C, which shows a dependence of film resistivity as a function of borane/silane ratio for films deposited at different temperatures (525° C., 550° C., and 575° C.). Thus, in some embodiments, deposition is performed at a temperature of between about 575-650° C.

The concentration of boron in the deposited film was determined by SIMS before and after an anneal performed at a temperature of 650° C. for a duration of 2 hours. The concentrations before and after anneal were substantially the same, indicating that boron is stable in the film. It is advantageous that very high concentrations of dopant in the film can be achieved by provided methods. For example, in some embodiments concentration of dopant (e.g., boron) in the film is at least about 10% atomic. Further, it has been demonstrated by SIMS that distribution of boron in the boron-doped film is very even, and that boron does not substantially diffuse into a silicon oxide layer adjacent the doped polysilicon layer. Thus, smooth, conductive and stable doped polysilicon films, having homogeneous distribution of dopant are provided.

### Apparatus

The deposition of smooth silicon and silicon germanium films is preferably implemented in a plasma enhanced chemical vapor deposition (PECVD) reactor. Such a reactor may take many different forms. Generally, the apparatus will include one or more chambers or “reactors” (sometimes including multiple stations) that house one or more wafers and are suitable for wafer processing. Each chamber may house one or more wafers for processing. The one or more chambers maintain the wafer in a defined position or positions (with or without motion within that position, e.g. rotation, vibration, or other agitation).

While in process, each wafer is held in place by a pedestal, wafer chuck and/or other wafer holding apparatus. For certain operations in which the wafer is to be heated, the apparatus may include a heater such as a heating plate. A wide variety of PECVD apparatuses can be used to practice provided methods. Examples of suitable apparatuses for practicing embodiments of the invention include a Vector™ (e.g., C23 Vector) or Sequel™ (e.g., C2 Sequel) reactor, produced by Novellus Systems of San Jose, Calif., and apparatuses described in the. U.S. application Ser. No. 12/970,853 filed Dec. 16, 2010, titled “SMOOTH SILICON-CONTAINING FILMS” naming Fox et al. as inventors, previously incorporated by reference in its entirety.

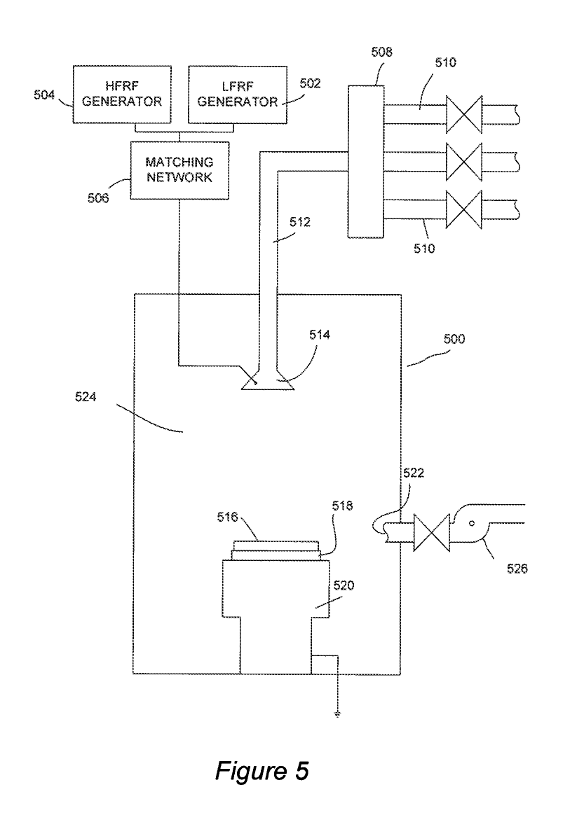

FIG. 5 provides a simple block diagram depicting various reactor components arranged for implementing the present invention. As shown, a reactor 500 includes a process chamber 524, which encloses other components of the reactor and serves to contain the plasma generated by a capacitor type system including a showerhead 514 working in conjunction with a grounded heater block 520. A high-frequency RF generator 502, connected to a matching network 506, and, optionally, a low-frequency RF generator 504 are connected to showerhead 514. The power and frequency supplied by matching network 506 is sufficient to generate a plasma from the process gas. In a typical process, the high frequency RF component is generally between about 2-60 MHz; in a preferred embodiment, the HF component is about 13.56 MHz. The LF component frequency (when used) can range between about 100 kHz and 2 MHz. A typical frequency range for LF plasma source is between about 50 kHz to 500 kHz,

Within the reactor, a wafer pedestal 518 supports a substrate 516. The pedestal typically includes a chuck, a fork, or lift pins to hold and transfer the substrate during and between the deposition. The chuck may be an electrostatic chuck, a mechanical chuck or various other types of chuck as are available for use in the industry and/or research.

The process gases are introduced via inlet 512. Multiple source gas lines 510 are connected to manifold 508. The gases may be premixed or not. Appropriate valving and mass flow control mechanisms are employed to ensure that the correct gases are delivered during the deposition and plasma treatment phases of the process. In case the chemical precursor(s) is delivered in the liquid form, liquid flow control mechanisms are employed. The liquid is then vaporized and mixed with other process gases during its transportation in a manifold heated above its vaporization point before reaching the deposition chamber.

Process gases exit chamber 500 via an outlet 522. A vacuum pump 526 (e.g., a one or two stage mechanical dry pump and/or a turbomolecular pump) typically draws process gases out and maintains a suitably low pressure within the reactor by a close loop controlled flow restriction device, such as a throttle valve or a pendulum valve.

The deposition of smooth silicon and silicon germanium films may be implemented on a multi-station or single station tool. In specific embodiments, the 300 mm Novellus Vector™ tool having a 4-station deposition scheme or the 200 mm Sequel™ tool having a 6-station deposition scheme are used. It is possible to index the wafers after every deposition until all the required depositions are completed, or multiple depositions can be conducted at a single station before indexing the wafer.

In certain embodiments, a system controller (not shown) is associated with the apparatus and is employed to control process conditions during deposition of the films, insert and remove wafers, etc. The controller will typically include one or more memory devices and one or more processors. The processor may include a CPU or computer, analog and/or digital input/output connections, stepper motor controller boards, etc.

In certain embodiments, the controller controls all of the activities of the deposition apparatus. The system controller executes system control software including sets of program instructions for controlling the timing, mixture of gases, chamber pressure, chamber temperature, wafer temperature, RF power levels, wafer chuck or susceptor position, and other parameters of a particular process. For example, instructions specifying flow rates of silicon-containing precursor and helium for silicon or silicon germanium film deposition may be included. In general, instructions may comprise instructions for process conditions for any of the processes described herein. The controller may comprise different or identical instructions for different apparatus stations, thus allowing the apparatus stations to operate either independently or synchronously.

Other computer programs stored on memory devices associated with the controller may be employed in some embodiments.

Typically there will be a user interface associated with controller. The user interface may include a display screen, graphical software displays of the apparatus and/or process conditions, and user input devices such as pointing devices, keyboards, touch screens, microphones, etc.

The computer program code for controlling the deposition processes can be written in any conventional computer readable programming language: for example, assembly language, C, C++, Pascal, Fortran or others. Compiled object code or script is executed by the processor to perform the tasks identified in the program.

The controller parameters relate to process conditions such as, for example, process gas composition and flow rates, temperature, pressure, plasma conditions such as RF power levels and the low frequency RF frequency, etc. These parameters are provided to the user in the form of a recipe, and may be entered utilizing the user interface.

Signals for monitoring the process may be provided by analog and/or digital input connections of the system controller. The signals for controlling the process are output on the analog and digital output connections of the deposition apparatus.

The system software may be designed or configured in many different ways. For example, various chamber component subroutines or control objects may be written to control operation of the chamber components necessary to carry out the inventive deposition processes. Examples of programs or sections of programs for this purpose include substrate positioning code, process gas control code, pressure control code, heater control code, and plasma control code.

A substrate positioning program may include program code for controlling chamber components that are used to load the substrate onto a pedestal or chuck and to control the spacing between the substrate and other parts of the chamber such as a gas inlet and/or target. A process gas control program may include code for controlling gas composition and flow rates and optionally for flowing gas into the chamber prior to deposition in order to stabilize the pressure in the chamber. A pressure control program may include code for controlling the pressure in the chamber by regulating, e.g., a throttle valve in the exhaust system of the chamber. A heater control program may include code for controlling the current to a heating unit that is used to heat the substrate. A plasma control program may include code for setting RF power levels applied to the process electrodes at the target and the wafer chuck.

Examples of chamber sensors that may be monitored during deposition and/or resputtering include mass flow controllers, pressure sensors such as manometers, and thermocouples located in pedestal or chuck. Appropriately programmed feedback and control algorithms may be used with data from these sensors to maintain desired process conditions.

Incorporation into Stacks

In many embodiments, provided smooth silicon or smooth silicon germanium films are incorporated into stacks of multiple layers, such as stacks used during fabrication of 3D memory. The low roughness of provided films is particularly advantageous for these applications, because large stacks having low roughness can be obtained. For example, smooth stacks containing at least about 10 layers, e.g., at least about 50 layers, containing at least about 30% of layers of smooth silicon or smooth silicon germanium provided herein can be prepared. In many embodiments, the measured surface roughness of the formed stacks in their entirety is less than about 10 Å, such as less than about 5 Å. Low roughness of stacks is a particularly advantageous property for lithographic patterning, which is typically performed after the stacks have been deposited. More generally, these films can be used in a variety of applications, not limited to fabrication of 3D memory.

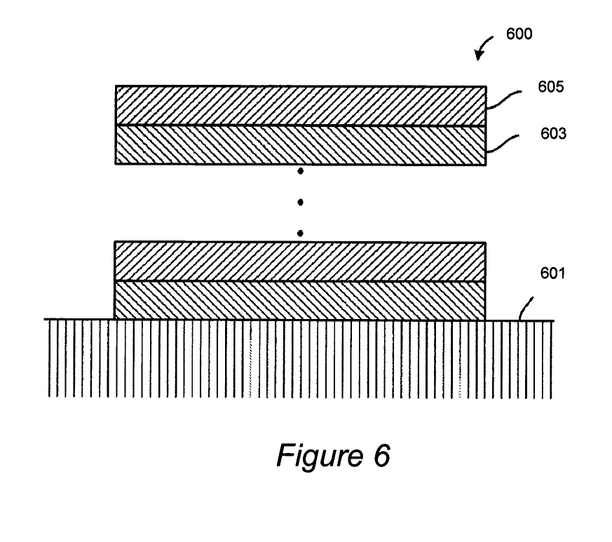

FIG. 6 is a schematic cross-sectional depiction of a stack of films in accordance with embodiments provided herein. The stack 600 is deposited on a substrate 601 and contains a plurality of alternating layers 603 and 605, at least some of t which are layers of smooth silicon or smooth silicon germanium provided herein. For example, in one embodiment one of the types of layers (e.g., 603) is smooth undoped polysilicon, and the other type of layers (e.g., 605) is a layer of doped polysilicon (e.g., boron-doped polysilicon), a layer of silicon germanium, a layer of silicon oxide, or a layer of silicon nitride. In another embodiment one of the types of layers (e.g., 603) is smooth silicon germanium, and the other type of layers (e.g., 605) is a layer of doped polysilicon (e.g., boron-doped polysilicon), undoped polysilicon, silicon oxide or silicon nitride. In yet another embodiment one of the types of layers (e.g., 603) is smooth doped polysilicon (e.g., boron-doped polysilicon), and the other type of layers (e.g., 605) is a layer of undoped polysilicon, silicon germanium, silicon oxide or silicon nitride. In some embodiments, it is preferable that all or most of the layers of the stack (including silicon oxide and silicon nitride layers, if present) are low-roughness layers having roughness of less than about 4 Å. Methods for depositing ultra-smooth silicon nitride and silicon oxide films are described in the U.S. application Ser. No. 12/970,853 filed Dec. 16, 2010, titled “SMOOTH SILICON-CONTAINING FILMS” naming Fox et al. as inventors, previously incorporated by reference in its entirety. In other embodiments, some of the layers of the stack may be deposited using conventional methods, and the stack as a whole would still have acceptable surface roughness, such as less than about 4 Å.

In some embodiments, the stacks contain between about 10-100 layers, where the layers alternate, e.g., smooth undoped polysilicon layer or a smooth silicon germanium layer alternates with a doped polysilicon layer, or smooth doped polysilicon layer alternates with a silicon nitride layer or a silicon oxide layer. The layers need not be of the same thickness, as some layers in the stack can be thicker than others, although the stacks may contain a plurality of alternating layers having substantially the same thickness. In some embodiments, alternating layers have a thickness in the range of between about 100-1500 Å, such as between about 150-400 Å.

Advantageously, in some embodiments deposition of alternating layers in the stack is performed in one PECVD process chamber without a vacuum break. In some embodiments deposition of alternating layers is performed at one station of a multi-station PECVD process chamber. The following are examples of several process sequences that can be employed (with or without a vacuum break between deposition of layers).

(1) Deposit a layer of smooth doped polysilicon (e.g., boron doped polysilicon) onto a layer of silicon oxide on a substrate; deposit a second layer of silicon oxide onto a layer of smooth doped polysilicon.

(2) Deposit a layer of smooth doped polysilicon (e.g., boron doped polysilicon) onto a layer of silicon nitride on a substrate; deposit a second layer of silicon nitride onto a layer of smooth doped polysilicon.

(3) Deposit a layer of smooth doped polysilicon (e.g., boron doped polysilicon) onto a layer of undoped polysilicon on a substrate; deposit a second layer of undoped polysilicon onto a layer of smooth doped polysilicon.

(4) Deposit a layer of smooth doped polysilicon (e.g., boron doped polysilicon) onto a layer of silicon germanium on a substrate; deposit a second layer of silicon germanium onto a layer of smooth doped polysilicon.

(5) Deposit a layer of smooth undoped polysilicon onto a layer of doped polysilicon on a substrate; deposit a second layer of doped polysilicon onto a layer of smooth undoped polysilicon.

(6) Deposit a layer of smooth silicon germanium onto a layer of doped polysilicon on a substrate; deposit a second layer of doped polysilicon onto a layer of smooth silicon germanium.

After the stacks have been formed they are typically subjected to photolithographic patterning, which involves applying photoresist to the substrate; exposing the photoresist to light; patterning the resist and transferring the pattern to the substrate and selectively removing the photoresist from the substrate. The apparatus/process described hereinabove may be used in conjunction with lithographic patterning tools or processes, for example, for the fabrication or manufacture of semiconductor devices, displays, LEDs, photovoltaic panels and the like. Typically, though not necessarily, such tools/processes will be used or conducted together in a common fabrication facility. Lithographic patterning of a film typically comprises some or all of the following steps, each step enabled with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

In some embodiments, the materials in the different layers of the stacks are selected such as to exhibit maximum etch-selectivity during patterning. For example, in some embodiments heavily doped polysilicon layers, which contain at least about 10% atomic of dopant, are preferred, as they can exhibit maximum etch selectivity vs. the layers they alternate with (e.g., undoped polysilicon). It is noted, that it is challenging to obtain such heavily-doped films using conventional methods, and provided methods offer a unique advantage in this respect. In some embodiments, a stack comprising layers of smooth boron-doped polysilicon containing at least about 10% atomic of boron, alternating with layers of undoped polysilicon or silicon germanium is deposited and then patterned, e.g., by reactive ion etching (RIE).

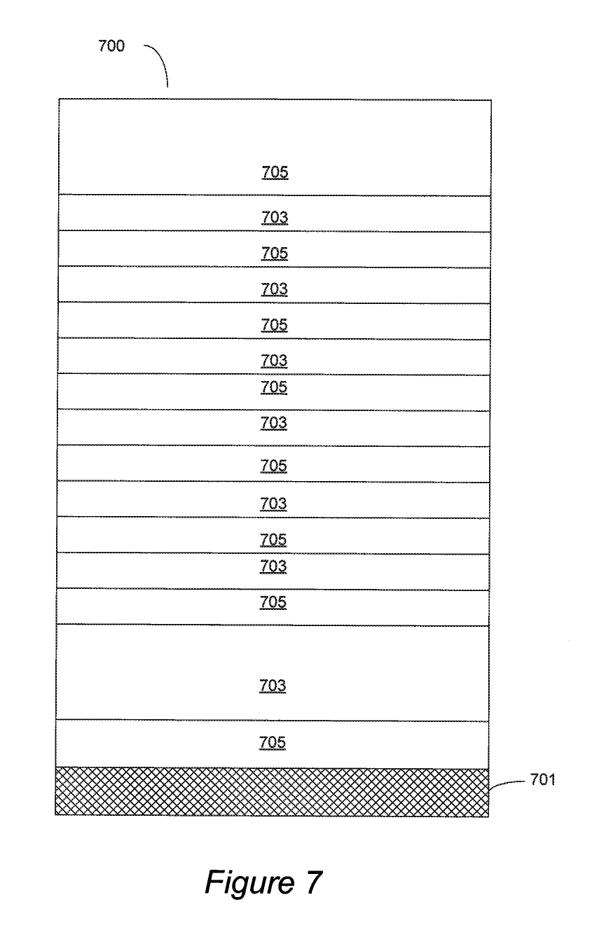

FIG. 7 illustrates a cross-sectional schematic depiction of experimentally obtained stack 700, where the stack contains fifteen layers on a substrate 701. The stack contains layers of smooth boron-doped polysilicon 703 deposited in accordance with methods provided herein which alternate with layers of smooth silicon oxide 705 deposited in accordance with the methods provided in application Ser. No. 12/970,853 filed Dec. 16, 2010, titled “SMOOTH SILICON-CONTAINING FILMS” naming Fox et al. as inventors, previously incorporated by reference in its entirety. The stack is formed by depositing a 500 Å layer of smooth silicon oxide on a substrate, followed by a 1000 Å layer of smooth boron-doped polysilicon, followed by six pairs of alternating smooth silicon oxide and smooth B-doped polysilicon layer, wherein each layer has a thickness of 300 Å. The stack is capped with a 1000 Å layer of smooth silicon oxide. The measured roughness of the entire stack having a thickness of 6,100 Å was 2.44 Å.

In other experiments stacks of alternating layers of smooth boron-doped polysilicon and smooth silicon oxide having 65 and 73 layers total were deposited. The surface roughness of obtained stacks of films was less than 3.5 Å in both cases.

What is claimed is:

1. A method for forming a smooth silicon film on a substrate in a plasma-enhanced chemical vapor deposition apparatus, the method comprising:
supplying a process gas comprising a silicon-containing reactant to the plasma-enhanced chemical vapor deposition apparatus; and
forming a plasma in said apparatus to deposit a smooth silicon film on the substrate, under conditions configured for depositing a silicon film characterized by roughness (Ra) of less than about 4 Å.

2. The method of claim 1, wherein the silicon-containing reactant is silane, and wherein the process gas comprises less than about 2% by volume of silane.

3. The method of claim 2, wherein the process gas comprises between about 0.2-1% by volume of silane.

4. The method of claim 2, wherein the deposited silicon film is a polycrystalline silicon film.

5. The method of claim 2, wherein the deposited silicon film is substantially free of Si—H bonds, as measured by FTIR.

6. The method of claim 2, wherein the process gas further comprises an inert gas.

7. The method of claim 2, wherein the process gas further comprises hydrogen.

8. The method of claim 2, wherein the deposited silicon film is doped and conductive, and is characterized by a resistivity of less than about 0.015 Ohm cm as-deposited.

9. The method of claim 8, wherein the process gas comprises diborane, and wherein the deposited silicon film is boron-doped.

10. The method of claim 1, wherein the process gas further comprises H₂ and wherein the deposited silicon film is substantially free of Si—H bonds as measured by FTIR.

11. The method of claim 1, wherein the process gas comprises between about 0.15-2% by volume of silane, and further comprises H₂

12. The method of claim 11, wherein the process gas comprises between about 1 and 15% by volume of H₂.

13. The method of claim 1, wherein the process gas comprises diborane and silane, and wherein diborane is provided in an amount of less than about 1.1% of the silane volume in the process gas, and wherein the deposited silicon film is substantially free of Si—H bonds as measured by FTIR.

14. The method of claim 1, wherein the process gas further comprises a dopant-containing reactant, and wherein the deposited smooth silicon film is doped with a dopant selected from the group consisting of boron, phosphorus, and arsenic.

15. The method of claim 1, wherein the process gas comprises diborane, and wherein the deposited silicon film is a conductive boron-doped film, characterized by a resistivity of less than about 0.015 Ohm cm.

16. The method of claim 1, wherein the process gas comprises silane and diborane, and wherein the diborane to silane volume ratio is between about 0.011 and 0.35.

17. The method of claim 1, wherein the deposited silicon film is a stable boron-doped film, comprising up to about 30% atomic of boron.

18. The method of claim 17, further comprising incorporating the stable boron-doped film into a film stack, comprising one or more layers of undoped silicon and/or undoped silicon germanium.

19. The method of claim 1, further comprising incorporating the smooth silicon film into a stack, comprising alternating layers of smooth silicon and a material selected from the group consisting of smooth silicon oxide and smooth silicon nitride.

20. The method of claim 1, further comprising depositing smooth silicon oxide or smooth silicon nitride over the smooth silicon film without a vacuum break.

21. The method of claim 1, wherein the smooth silicon film is deposited at a temperature of between about 350-650° C., and at a pressure of between about 0.5-8 Torr, wherein the deposition rate of the smooth silicon film is at least about 100 Å/minute.

22. The method of claim 1, wherein the smooth silicon film is incorporated into a stack of layers without an anneal.

23. The method of claim 1, wherein the smooth silicon film is further annealed by heating the substrate at a temperature of at least about 400° C.

24. A method for forming a smooth silicon germanium film on a substrate in a plasma-enhanced chemical vapor deposition apparatus, the method comprising:
supplying a process gas comprising a silicon-containing reactant and a germanium-containing reactant to the plasma enhanced chemical vapor deposition apparatus; and
forming a plasma in said apparatus to deposit a smooth silicon germanium
film on the substrate, under conditions configured for depositing a silicon germanium film characterized by roughness (Ra) of less than about 4 Å.

25. The method of claim 25, further comprising incorporating the smooth silicon germanium film into a stack comprising alternating layers of smooth silicon germanium and a material selected from the group consisting of silicon oxide, silicon nitride, doped silicon, and undoped silicon.

26. The method of claim 1 further comprising the steps of:
applying photoresist to the substrate;
exposing the photoresist to light;
patterning the resist and transferring the pattern to the substrate;
and selectively removing the photoresist from the substrate.

27. An apparatus for depositing a smooth silicon film, comprising:
(a) a PECVD process chamber having an inlet for introduction of a process gas; and
(b) a controller comprising program instructions for conducting a process comprising supplying a process gas comprising a silicon-containing reactant to the PECVD process chamber; and
forming a plasma in said process chamber to deposit a smooth silicon film on the substrate, wherein roughness of the deposited film is less than about 4 Å.

28. A non-transitory computer machine-readable medium comprising program instructions for control of a PECVD apparatus, the program instructions comprising,
code for supplying a process gas comprising a silicon-containing reactant to the PECVD process chamber; and
forming a plasma in said process chamber to deposit a smooth silicon film on the substrate, wherein roughness of the deposited film is less than about 4 Å.

29. A system comprising the deposition apparatus of claim 26 and a stepper.
